(19) United States
(12) Patent Application Publication
(10) Pub. No.: US 2022/0239064 A1
(43) Pub. Date: Jul. 28, 2022

(54) Light Emitting Apparatus, Projector, And Method For Manufacturing Light Emitting Apparatus

(71) Applicant: Seiko Epson Corporation, Tokyo (JP)

(72) Inventor: Takashi MIYATA, Shiojiri (JP)

(21) Appl. No.: 17/585,627

(22) Filed: Jan. 27, 2022

(30) Foreign Application Priority Data
Jan. 28, 2021 (JP) 2021-011738

(51) Int. Cl. H01S 5/042; H01S 5/34; H01S 5/40

(52) U.S. Cl. CPC H01S 5/04256; G03B 21/2033; H01S 5/4025; H01S 5/341

(57) ABSTRACT

A light emitting apparatus according to an aspect of the present disclosure includes a substrate, a columnar section group including a plurality of columnar sections each having a laminated structure of a first semiconductor layer, a light emitting layer, and a second semiconductor layer, and an electrode via which electric current is injected into the plurality of columnar sections. The plurality of columnar sections include a plurality of first columnar sections and a plurality of second columnar sections disposed around the plurality of first columnar sections. The second columnar sections each have the shape of each of the first columnar sections except that part of the shape is missing. The second columnar sections are lower than the first columnar sections. The electrode is electrically insulated from the plurality of second columnar sections.

The present application is based on, and claims priority from JP Application Serial Number 2021-011738, filed Jan. 28, 2021, the disclosure of which is hereby incorporated by reference herein in its entirety.

### BACKGROUND

### 1. Technical Field

The present disclosure relates to a light emitting apparatus, a projector, and a method for manufacturing the light emitting apparatus.

### 2. Related Art

There has been a known light emitting apparatus including a plurality of nano-structural elements having a periodic structure. JP-A-2013-239718 discloses a semiconductor optical device array including a semiconductor substrate, a plurality of nanocolumnar crystal elements provided on the semiconductor substrate, and active layers provided on the plurality of nanocolumnar crystal elements. Nano-structural elements of this type each have a columnar shape and are also called, for example, nanocolumns, nanowires, nanorods, and nanopillars.

However, in a light emitting apparatus including nano-structural elements, a predetermined amount of light emission may not be produced because leakage current causes a predetermined amount of current to be unlikely to flow to the proper light emitting region, unintended light emission may occur in regions other than the proper light emitting region, and other problems may occur.

### SUMMARY

To solve the problems described above, a light emitting apparatus according to an aspect of the present disclosure includes a substrate, a columnar section group provided on the substrate and formed from a plurality of columnar sections each having a laminated structure formed from a first semiconductor layer, a light emitting layer, and a second semiconductor layer, and electrodes which are provided on the plurality of columnar sections and via which electric current is injected into the plurality of columnar sections. The plurality of columnar sections include a plurality of first columnar sections and a plurality of second columnar sections disposed around the plurality of first columnar sections. The second columnar sections each have a shape of each of the first columnar sections except that part of the shape is missing. The second columnar sections are lower than the first columnar sections. The electrodes are electrically insulated from the plurality of second columnar sections.

A projector according to another aspect of the present disclosure includes the light emitting apparatus according to the aspect of the present disclosure.

A method for manufacturing a light emitting apparatus according to another aspect of the present disclosure includes forming at a substrate a plurality of columnar sections each having a laminated structure formed from a first semiconductor layer, a light emitting layer, and a second semiconductor layer, forming a columnar section group by etching the plurality of columnar sections, etching the columnar section group, and forming electrodes electrically coupled to the columnar section group. In the forming of the plurality of columnar sections, the plurality of columnar sections include a plurality of first columnar sections and a plurality of second columnar sections disposed around the plurality of first columnar sections. The second columnar sections each have a shape of each of the first columnar sections except that part of the shape is missing. In the etching of the columnar section group, the second columnar sections are etched so as to be lower than the first columnar sections. In the forming of the electrodes, the electrodes are formed so as to be electrically insulated from the second columnar sections.

### BRIEF DESCRIPTION OF THE DRAWINGS

FIG. 1 is a schematic configuration diagram of a projector according to an embodiment.

FIG. 2 is a plan view diagrammatically showing a light emitting apparatus according to the embodiment.

FIG. 3 is a cross-sectional view of the light emitting apparatus taken along the line III-III in FIG. 2.

FIG. 4A is a cross-sectional view showing one step in the process of manufacturing the light emitting apparatus.

FIG. 4B is a cross-sectional view showing the step following the step shown in FIG. 4A.

FIG. 4C is a cross-sectional view showing the step following the step shown in FIG. 4B.

FIG. 4D is a cross-sectional view showing the step following the step shown in FIG. 4C.

FIG. 4E is a cross-sectional view showing the step following the step shown in FIG. 4D.

FIG. 4F is a cross-sectional view showing the step following the step shown in FIG. 4E.

FIG. 5 is a plan view of a light emitting section.

FIG. 6 describes problems with a light emitting apparatus of related art.

### DESCRIPTION OF EXEMPLARY EMBODIMENTS

An embodiment of the present disclosure will be described below with reference to the drawings.

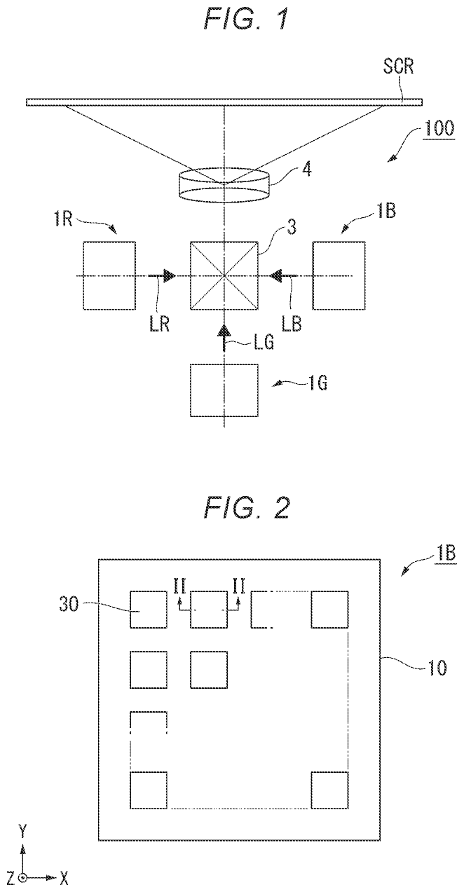

FIG. 1 is a schematic configuration diagram of a projector according to the present embodiment.

In the following drawings, components are drawn at different dimensional scales in some cases for clarification of each of the components.

A projector 100 according to the present embodiment is a projection-type image display apparatus that projects an image on a screen SCR, as shown in FIG. 1. The projector 100 includes light emitting apparatuses 1R, 1G, and 1B, a cross dichroic prism 3, and a projection optical apparatus 4. The configuration of the light emitting apparatuses 1R, 1G, and 1B will be described later.

The light emitting apparatus 1R emits red light. The light emitting apparatus 1G emits green light. The light emitting apparatus 1B emits blue light. The light emitting apparatuses 1R, 1G, and 1B can directly form video images by modulating respective light emitting sections as video image pixels in accordance with image information without using, for example, light modulators, such as liquid crystal light valves.

The color light emitted from each of the light emitting apparatuses 1R, 1G, and 1B enters the cross dichroic prism 3. The cross dichroic prism 3 combines the red light emitted from the light emitting apparatus 1R, the green light emitted from the light emitting apparatus 1G, and the blue light emitted from the light emitting apparatus 1B with one another and guides the combined light to the projection optical apparatus 4. The projection optical apparatus 4 enlarges video images formed by the light emitting apparatuses 1R, 1G, and 1B and projects the enlarged video images on the screen SCR. The projection optical apparatus 4 is formed from a single projection lens or a plurality of projection lenses.

Specifically, the cross dichroic prism 3 is formed by bonding four right-angled prisms to each other, and a dielectric multilayer film that reflects the red light and a dielectric multilayer film that reflects the blue light are disposed at the inner surfaces of the combined prisms so that the two films form a cross. The dielectric multilayer films combine the red light, the green light, and the blue light with one another to form light representing a color image. The combined light is projected by the projection optical apparatus 4 on the screen SCR to display an enlarged image.

The light emitting apparatuses 1R, 1G, and 1B have the same basic configuration except that the wavelength bands to which the light emitted from the light emitting apparatuses 1R, 1G, and 1B differ from one another. The configuration of the light emitting apparatus 1B will therefore be described by way of example below in detail.

FIG. 2 is a plan view diagrammatically showing the configuration of the light emitting apparatus 1B.

The configuration of each portion of the light emitting apparatus 1B will be described below by using an XYZ orthogonal coordinate system. Axes used in the description are defined as follows: An axis X is an axis parallel to one set of facing sedge of a light emitting region of the light emitting apparatus 1B, the light emitting region having a rectangular planar shape when viewed in the direction in which the light emitting apparatus 1B outputs light; an axis Y is an axis parallel to the other set of facing edges of the light emitting region; and an axis Z is an axis perpendicular to the axes X and Y. When the axis parallel to the direction in which the light exits is defined as the optical axis of the light emitting apparatus 1B, the Z axis is parallel to the optical axis of the light emitting apparatus 1B.

The light emitting apparatus 1B includes a plurality of light emitting sections 30 arranged in an array as shown in FIG. 2. In the present embodiment, the plurality of light emitting sections 30 are arranged in a matrix along the axes X and Y. The light emitting apparatus 1B can thus form a self-luminous imager that forms video images with the light emitting sections 30 each serving as a single pixel.

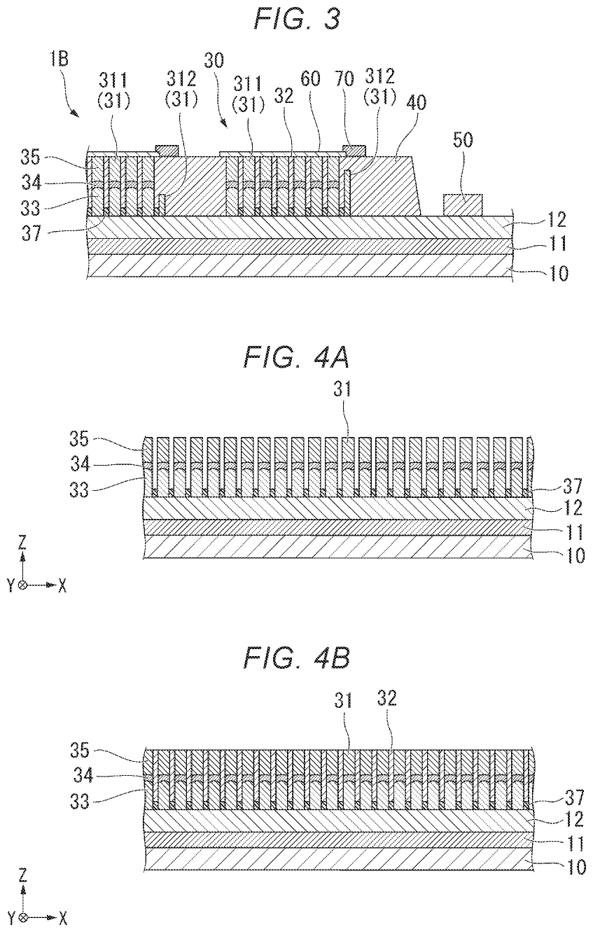

FIG. 3 is a cross-sectional view showing the configurations of key parts of the light emitting apparatus 1B. FIG. 3 shows the cross-section of the light emitting apparatus 1B taken along the line III-III in FIG. 2.

The light emitting apparatus 1B includes a substrate 10, a reflection layer 11, a semiconductor layer 12, the light emitting sections 30, an insulating layer 40, first electrodes 50, second electrodes 60, and wiring lines 70, as shown in FIG. 3.

The second electrodes 60 in the present embodiment correspond to the electrode in the claims.

In the description of the present embodiment, in the axis-Z direction, the direction in which elements of the laminated structure that forms each of the light emitting sections 30 are laminated on the substrate 10 is oriented toward an upper side, and the direction opposite the direction in which the elements of the laminated structure are laminated is oriented toward a lower side. However, the definition described above does not limit the direction in which the light emitting apparatus 1B is installed when it is used. The view in the lamination direction of the laminated structure, that is, in the direction of the optical axis of the light emitting apparatus 1B is referred to as a plan view.

The substrate 10 is formed, for example, from a silicon (Si) substrate, a gallium nitride (GaN) substrate, or a sapphire substrate. The reflection layer 11 is provided at the upper surface of the substrate 10. The reflection layer is formed, for example, from a laminate in which AlGaN layers and GaN layers are alternately laminated on each other or a laminate in which AlInN layers and GaN layers are alternately laminated on each other. The reflection layer 11 reflects light generated by light emitting layers in the nanocolumns, which will be described later, toward the side opposite from the substrate 10. A heat sink may be provided at the lower surface of the substrate 10 to dissipate heat generated by the light emitting sections 30.

The semiconductor layer 12 is provided on the reflection layer 11. The semiconductor layer 12 is a layer made of an n-type semiconductor material and is formed, for example, from an n-type GaN layer, specifically, a GaN layer doped with Si.

The light emitting sections 30 each include a plurality of nanocolumns 31 and a light propagation layer 32. The nanocolumns 31 are each a columnar crystal structural element that protrudes and extends upward from the semiconductor layer 12. The nanocolumns 31 each have, for example, a polygonal, circular, or elliptical columnar shape. In the present embodiment, the nanocolumns 31 each have a circular columnar shape. The nanocolumns 31 have a diameter in the order of nanometers, specifically, for example, greater than or equal to 10 nm but smaller than or equal to 500 nm. The dimension of the nanocolumns 31 in the lamination direction, that is, the height of the nanocolumns 31, is, for example, greater than or equal to 0.1 μm but smaller than or equal to 5 μm.

The nanocolumns 31 in the present embodiment correspond to the columnar sections in the claims.

When the nanocolumns 31 each have a circular planar shape, the diameter of the nanocolumns 31 is the diameter of the circular shape, and when the nanocolumns 31 each have a non-circular planar shape, the diameter of the nanocolumns 31 is the diameter of the minimum circle containing the non-circular shape therein. For example, when the nanocolumns 31 each have a polygonal planar shape, the diameter of the nanocolumns 31 is the diameter of a minimum circle containing the polygonal shape therein. When the nanocolumns 31 each have an elliptical planar shape, the diameter of the nanocolumns 31 is the diameter of a minimum circle containing the elliptical shape therein.

In the case where the nanocolumns 31 each have a circular planar shape, the center of each of the nanocolumns 31 is the center of the circular shape, and in the case where the nanocolumns 31 each have a non-circular planar shape, the center of each of the nanocolumns 31 is the center of the minimum circle containing the non-circular shape therein. For example, in the case where the nanocolumns 31 each have a polygonal planar shape, the center of each of the nanocolumns 31 is the center of a minimum circle containing the polygonal shape therein. In the case where the nanocolumns 31 each have an elliptical planar shape, the center of each of the nanocolumns 31 is the center of a minimum circle containing the elliptical shape therein.

The plurality of nanocolumns 31 are arranged in a predetermined direction at predetermined intervals in the plan view, as shown in FIG. 5. The nanocolumns 31 can provide a photonic crystal effect, which traps the light emitted by light emitting layers 34 in the in-plane direction of the substrate 10 and outputs the light in the lamination direction. The in-plane direction of the substrate 10 is the direction along a plane perpendicular to the lamination direction.

The nanocolumns 31 each have a first semiconductor layer 33, the light emitting layer 34, and a second semiconductor layer 35. Specifically, the nanocolumns 31 each have a laminated structure in which the first semiconductor layer 33, the light emitting layer 34, and the second semiconductor layer 35 are laminated in this order from the side facing the semiconductor layer 12. The layers that form each of the nanocolumns 31 are formed by epitaxial growth, as will be described later.

The first semiconductor layer 33 is provided on the semiconductor layer 12. The first semiconductor layer 33 is provided between the semiconductor layer 12 and the light emitting layer 34. The first semiconductor layer 33 is formed from an n-type semiconductor layer, for example, an n-type GaN layer doped with Si. In the present embodiment, the first semiconductor layer 33 is made of the same material as the semiconductor layer 12 is.

The light emitting layer 34 is provided on the first semiconductor layers 33. The light emitting layer 34 is provided between the first semiconductor layer 33 and the second semiconductor layer 35. The light emitting layer 34 has, for example, a quantum well structure in which a large number of GaN layers and InGaN layers are alternately laminated on each other. The light emitting layer 34 emits light when electric current is injected thereinto via the first semiconductor layer 33 and the second semiconductor layer 35. The numbers of GaN layers and InGaN layers that form the light emitting layer 34 are each not limited to a specific number. In the present embodiment, the light emitting layer 34 emits, for example, blue light that belongs to a blue wavelength band ranging from 430 to 470 nm.

The second semiconductor layer 35 is provided on the light emitting layer 34. The second semiconductor layer 35 differs from the first semiconductor layer 33 in terms of conductivity type. That is, the second semiconductor layer 35 is a layer made of a p-type semiconductor material and is formed, for example, from a p-type GaN layer doped with Mg. The first semiconductor layer 33 and the second semiconductor layer 35 function as a cladding layer having the function of confining the light within the light emitting layer 34.

The light propagation layer 32 is provided so as to surround each of the nanocolumns 31 in the plan view. The light propagation layer 32 is therefore provided in the gap between adjacent nanocolumns 31. The refractive index of the light propagation layer 32 is smaller than the refractive index of the light emitting layer 34. The light propagation layer 32 is formed, for example, from a GaN layer or a titanium oxide (TiO₂) layer. The GaN layer that forms the light propagation layer 32 may be of i-type, n-type, or p-type. The light propagation layer 32 causes the light generated in the light emitting layer 34 to propagate in the planar direction.

In each of the light emitting sections 30, the laminate of the p-type second semiconductor layer 35, the light emitting layer 34, which has been doped with no impurity, and the n-type first semiconductor layer 33 forms a pin diode. The bandgap of each of the first semiconductor layer 33 and the second semiconductor layer 35 is wider than the bandgap of the light emitting layer 34. In each of the light emitting sections 30, when a voltage corresponding to the forward bias voltage for the pin diode is applied to the space between the first electrode 50 and the second electrode 60 so that current is injected into the pin diode, electrons and holes recombine with each other in the light emitting layer 34. The recombination causes light emission.

The first semiconductor layers 33 and the second semiconductor layers 35 cause the light generated in the light emitting layers 34 to propagate through the light propagation layer 32 in the in-plane direction of the substrate 10. In this process, the photonic crystal effect provided by the nanocolumns 31 causes the light to form a standing wave, which is confined in the in-plane direction of the substrate 10. The confined light receives gain in the light emitting layers 34 and undergoes laser oscillation. That is, the plurality of nanocolumns 31 cause the light generated in the light emitting layer 34 to resonate in the in-plane direction of the substrate 10, resulting in laser oscillation. Specifically, the light generated in the light emitting layers 34 resonates in the in-plane direction of the substrate 10 in a resonant section formed by the plurality of nanocolumns 31, resulting in laser oscillation. The positive first-order diffracted light and the negative first-order diffracted light generated by the resonance then travel as laser light in the lamination direction (axis-Z direction).

In the light emitting apparatus 1B, the refractive indices and thicknesses of the first semiconductor layers 33, the second semiconductor layers 35, and the light emitting layers 34 are so designed that the intensity of the light propagating in the planar direction is maximized in the light emitting layers 34 in the axis-Z direction.

In the present embodiment, out of the laser light traveling in the lamination direction, the laser light traveling toward the substrate 10 is reflected off the reflection layer 11 and travels toward the second electrodes 60. The light emitting sections 30 can thus emit the light via the side facing the second electrodes 60.

A mask layer 37 is provided on the semiconductor layer 12 as shown in FIG. 3. The mask layer 37 is provided between the light propagation layer 32 and the semiconductor layer 12. The mask layer 37 functions as a mask for growing the films that form the nanocolumns 31 selectively in specific regions on the semiconductor layer 12 in the process of manufacturing the light emitting sections 30. The mask layer 37 is formed, for example, from a silicon oxide layer or a silicon nitride layer.

The insulating layer 40 is provided between adjacent light emitting sections 30 on the semiconductor layer 12. The insulating layer 40 is formed, for example, from a silicon oxide layer. The insulating layer 40 has the function of planalizing the unevenness, on the semiconductor layer 12, formed by the light emitting sections 30 and protecting the light emitting sections 30.

The first electrodes 50 are provided on the semiconductor layer 12 and on the side facing the light emitting sections 30. The first electrodes 50 are provided in correspondence with the light emitting sections 30 and electrically coupled to the light emitting sections 30 via the semiconductor layer 12. The first electrodes 50 form, for example, part of transistors provided in correspondence with the light emitting sections 30, for example, the gate electrodes of the transistors, and can control the amount of current to be injected into the nanocolumns 31.

The first electrodes 50 may be in ohmic contact with the semiconductor layer 12. In the example shown in FIG. 3, the first electrodes 50 are electrically coupled to the first semiconductor layers 33 of the nanocolumns 31 via the semiconductor layer 12. The first electrodes 50 are one of the electrodes for injecting the current into the light emitting layers 34. The first electrodes 50 are each, for example, be a metal layer made, for example, of Ni, Ti, Cr, Pt, or Au or a laminated metal film that is a laminate of the metal layers made of the elements described above.

The second electrodes 60 are provided on the light emitting sections 30. The second electrodes 60 are the other one of the electrodes for injecting the current into the light emitting layers 34. The second electrodes 60 are provided in correspondence with the light emitting sections 30. The second electrodes 60 are provided so as to be in contact with the nanocolumns 31 and part of the light propagation layer 32.

The second electrodes 60 need to be light transmissive as well as electrically conductive. The second electrodes 60 are each therefore formed from a metal layer made, for example, of Ni, Ti, Cr, Pt, or Au, a laminated metal film that is a laminate of the metal layers made of the elements described above, or a transparent electrically conductive layer made, for example, of ITO (indium tin oxide) or IZO (indium zinc oxide). When a metal layer is used, the thickness of the metal layer is desirably as thin as a few tens of nanometers in order to be light transmissive. The second electrodes 60 may each have a laminated structure formed from a contact layer formed from the metal layer described above and a transparent electrically conductive layer. In this case, the contact layer provides the effect of increasing the electrical conductivity between the transparent electrically conductive layer and the corresponding nanocolumn 31. The light generated in the light emitting layers 34 exits through the second electrodes 60.

The wiring lines 70 are provided on the insulating layer 40 with part of the wiring lines 70 overlapping with the second electrodes 60 in the plan view. The wiring lines 70 are electrically coupled to the second semiconductor layers 35 in the nanocolumns 31 in the light emitting sections 30 via the second electrodes 60. The wiring lines 70 are formed, for example, from a metal layer made, for example, of Ni, Ti, Cr, Pt, or Au or a laminated metal film that is a laminate of the metal layers made of the elements described above.

The wiring lines 70 are coupled, for example, via bonding wires, to a drive circuit provided on the substrate 10 in a region that is not shown. The first electrodes 50 are coupled, for example, via bonding wires, to the drive circuit provided on the substrate 10 in the region that is not shown. Based on the configuration described above, driving the drive circuit allows the light emitting sections 30 to inject electric current into the light emitting layers 34 of the nanocolumns 31 via the first electrodes 50 and the second electrodes 60.

FIG. 5 is a plan view of one of the light emitting sections 30. In FIG. 5, all nanocolumns 31 that are initially formed in the manufacturing process described later are drawn with broken lines, and nanocolumns 31 that are eventually left are drawn with solid lines. In FIG. 5, the wiring lines 70 and other components are omitted.

The light emitting sections 30 in the present embodiment each have a circular shape in the plan view, as shown in FIG. 5. The light emitting sections 30 include nanocolumn groups 31A each formed from a plurality of nanocolumns 31 each having a laminated structure formed from the first semiconductor layer 33, the light emitting layer 34, and the second semiconductor layer 35, as described above.

The nanocolumn groups 31A in the present embodiment correspond to the columnar section group in the claims.

The plurality of nanocolumns 31 include a plurality of first nanocolumns 311 and a plurality of second nanocolumns 312 disposed around the plurality of first nanocolumns 311. The number of second nanocolumns 312 is smaller than the number of first nanocolumns 311. In the plan view, the second electrodes 60 overlaps with the plurality of first nanocolumns 311 and the plurality of second nanocolumns 312.

The first nanocolumns 311 in the present embodiment correspond to the first columnar section in the claims. The second nanocolumns 312 in the present embodiment correspond to the second columnar section in the claims.

In the plan view, the plurality of first nanocolumns 311 are disposed in positions shifted toward the center of the nanocolumn group 31A. The first nanocolumns 311 each have a circular planar shape. In contrast, the plurality of second nanocolumns 312 are disposed around the plurality of first nanocolumns 311 at the periphery of the nanocolumn group 31A.

The second nanocolumns 312 each have a partially missing circular planar shape. That is, in the plan view, a second nanocolumn 312 has the shape of a first nanocolumn 311 except that part of the shape is missing. Therefore, in the plan view, the area of a second nanocolumn 312 is smaller than that of a first nanocolumn 311. The ratio of the area of a second nanocolumn 312 to the area of a first nanocolumn 311 is not limited to a specific value. All the second nanocolumns 312 do not have the same planar shape but have randomly different planar shapes. In the present embodiment, the second nanocolumns 312 each have a partially missing circular planar shape, that is, a second nanocolumn 312 has the shape of a first nanocolumns 311 except that part of the shape is missing in the plan view. The situation described above is, however, not limited to the plan view. A second nanocolumn 312 may have the shape of a first nanocolumn 311 except that part of the shape is missing in any view.

The second nanocolumns 312 are lower than the first nanocolumns 311, as shown in FIG. 3. Specifically, the height of the second nanocolumns 312 is smaller than or equal to ⅘ of the height of the first nanocolumns 311. The second nanocolumns 312 do not have the same height but have randomly different heights. The height of the nanocolumns 31 is greater than or equal to 0.1 μm but smaller than or equal to 5 μm, and more specifically, the height of the first nanocolumns 311 ranges, for example, from about 800 to 1500 nm. The height of the second nanocolumns 312 therefore ranges, for example, from about 640 to 1200 nm.

The second semiconductor layers 35 of the plurality of first nanocolumns 311 are in contact with the respective second electrodes 60. The second electrodes 60 are therefore each electrically coupled to the plurality of first nanocolumns 311 at the center of the corresponding nanocolumn group 31A. In contrast, the plurality of second nanocolumns 312 are not in contact with the second electrodes 60. The second electrodes 60 are therefore electrically insulated from the plurality of second nanocolumns 312 at the periphery of the corresponding nanocolumn group 31A. In the present embodiment, the second electrodes 60 are electrically insulated from the second nanocolumns 312 via the insulating layer 40. The second electrodes 60 may be insulated from the second nanocolumns 312 via air gaps.

A method for manufacturing the light emitting apparatus 1B according to the present embodiment will be described below.

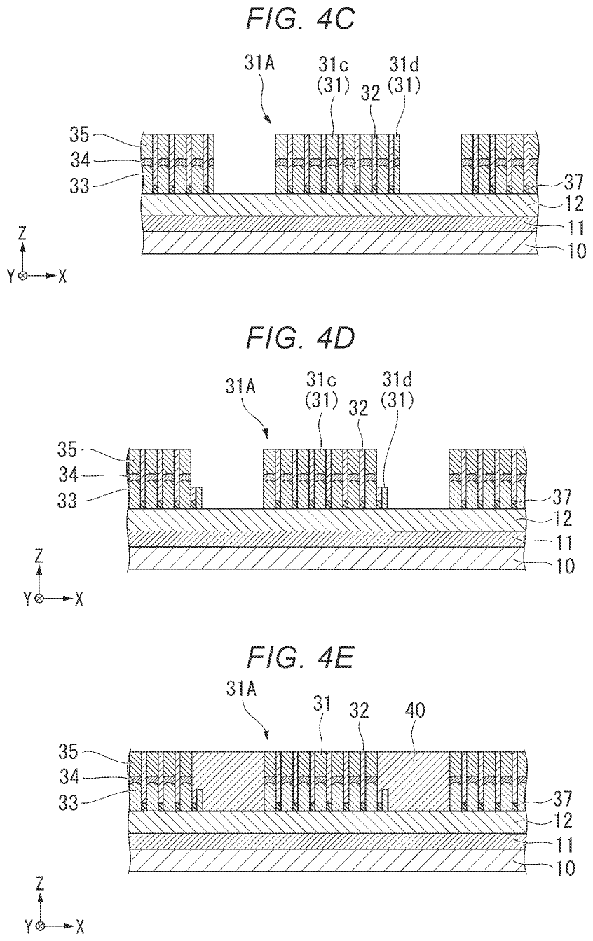

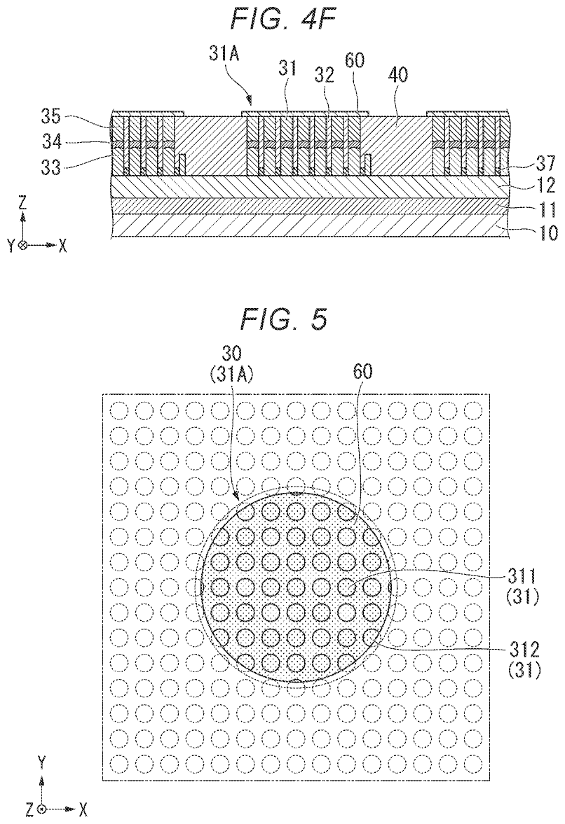

FIGS. 4A to 4F are each a cross-sectional view showing one of the steps in the process of manufacturing the light emitting apparatus 1B.

First, a metal film is deposited on the substrate 10, for example, by using sputtering or vapor deposition to form the reflection layer 11. The semiconductor layer 12 is then formed on the reflection layer 11 by epitaxial growth. Examples of the method for the epitaxial growth may include metal organic chemical vapor deposition (MOCVD) and molecular beam epitaxy (MBE).

A plurality of nanocolumns 31 are then formed over the entire surface of the semiconductor layer 12, as shown in FIG. 4A. Specifically, prior to the formation of the nanocolumns 31, the mask layer 37 having a large number of openings is formed on the semiconductor layer 12. The mask layer 37 is formed, for example, by film formation using chemical vapor deposition (CVD) or sputtering and patterning using photolithography and etching.

The mask layer 37 having openings can then be used as a mask to simultaneously form the plurality of nanocolumns 31 by epitaxially growing the first semiconductor layers 33, the light emitting layers 34, and the second semiconductor layers 35 in this order on the semiconductor layer 12, for example, by using MOCVD or MBE.

An insulating film is then deposited onto portions around the nanocolumns 31 to form the light propagation layer 32, as shown in FIG. 4B. In this process, it is desirable to use, for example, atomic layer deposition (ALD) to allow the deposition of the insulating film in the minute gaps between adjacent nanocolumns 31.

The plurality of nanocolumns 31 are then patterned by photolithography and etching using a resist pattern (not shown), as shown in FIG. 4C. The plurality of nanocolumns 31 are therefore divided into portions in the form of islands, so that a plurality of nanocolumn groups 31A are formed. In this step, a hard mask, which can ensure a larger etching selection ratio, may be used in place of the resist pattern.

In this process, since the plurality of nanocolumns 31 are arranged at equal intervals in each of the nanocolumn groups 31A, at least part of the nanocolumns 31 arranged along the outer circumference of the nanocolumn group 31A only partially overlap with the periphery of the resist pattern, as shown in FIG. 5. The portions, of the nanocolumn 31 at the outer circumference, that extend off the resist pattern are therefore etched away. Furthermore, any nanocolumn 31 completely covered with the resist pattern but located at the outer circumference is likely to be over-etched or otherwise processed and partially lost. As a result, nanocolumns 31d, which have been partial lost and therefore thinner than nanocolumns 31c in a central portion, are formed in an outer circumferential portion of each of the nanocolumn groups 31A. At this point of time, the thin nanocolumns 31d in the circumferential portion of each of the nanocolumn groups 31A are flush with the nanocolumns 31c in the central portion.

Etching is then performed to reduce the height of the thin nanocolumns 31d in the circumferential portion of each of the nanocolumn groups 31A, as shown in FIG. 4D. Specifically, wet etching using an alkaline chemical or plasma etching with an additive chlorine-based gas is performed. The etching is so performed for an appropriately adjusted etching period that the height of the nanocolumns 31d in the circumferential portion of each of the nanocolumn groups 31A is substantially smaller than or equal to ⅘ of the height of the nanocolumns 31c in the central portion. The etching in this step is desirably performed under lighter conditions than the etching in the previous step. This step may be carried out with the resist pattern used in the previous step left or after the resist pattern used in the previous step is removed.

An insulating film is deposited so as to fill the spaces between the nanocolumn groups 31A to form the insulating layer 40, as shown in FIG. 4E. In this process, the insulating layer 40 can be formed, for example, by film formation using a coating method, such as spin coating. The thickness of the insulating layer 40 is desirably equal to or greater than the height of the nanocolumns 31. When the thickness of the insulating layer 40 is greater than the height of the nanocolumns 31 and the nanocolumn groups 31A are embedded in the insulating layer 40, openings for contact with the second electrodes 60 may be formed in the following step.

The second electrodes 60, which will be electrically coupled to the nanocolumns 31 of the nanocolumn groups 31A, are then formed, as shown in FIG. 4F. Specifically, the second electrodes 60 are formed by film formation and patterning of a metal film or a transparent electrically conductive layer, for example, by using sputtering or vacuum vapor deposition.

The wiring lines 70 are then formed by film formation using sputtering or vacuum vapor deposition, and patterning. The light emitting apparatus 1B according to the present embodiment shown in FIG. 3 is thus completed. Furthermore, the formation of the first electrodes 50, the implementation of the drive circuit, and the electrical coupling of the drive circuit to the first electrodes 50 and the second electrodes 60 through wire bonding are performed.

### Effects of Present Embodiment

Problems with light emitting apparatuses of related art will first be described.

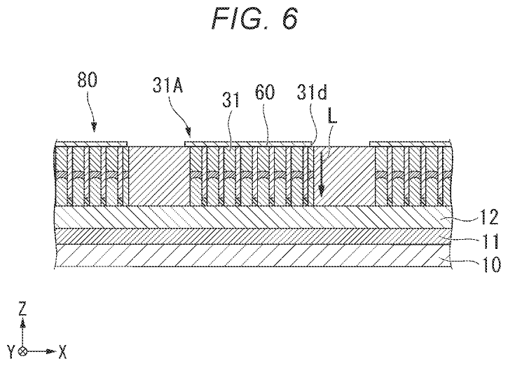

FIG. 6 describes the problems with a light emitting apparatus 80 of related art. In FIG. 6, components common to those in FIG. 3 have the same reference characters.

As mentioned in the above description of the manufacturing method, the thin nanocolumns 31d each partially missing tend to be left at the outer circumference of each of the nanocolumn groups 31A, as shown in FIG. 6. The thus shaped nanocolumns 31d, although the shapes thereof are imperfect, are electrically coupled to the second electrodes 60 and therefore form paths of leakage current L due to disorder in the crystal structure and other factors. As a result, the following problems may occur: a decrease in light emission efficiency causes a decrease in a predetermined amount of light emission; the wavelength at which the light emits is unstable; and unintended light emission occurs in regions other than the proper light emission region.

To address the problems described above, the light emitting apparatus 1B according to the present embodiment includes the substrate 10, the nanocolumn groups 31A each formed from the plurality of nanocolumns 31 each having the laminated structure formed from substrate 10, the first semiconductor layer 33, the light emitting layer 34, and the second semiconductor layer 35, and the second electrodes 60, which are provided on the plurality of nanocolumns 31 and via which electric current is injected into the plurality of nanocolumns 31. The plurality of nanocolumns 31 include a plurality of first nanocolumns 311 and a plurality of second nanocolumns 312 disposed around the plurality of first nanocolumns 311. In the plan view, the second nanocolumns 312 each have the shape of each of the first nanocolumns 311 except that part of the shape is missing. The second nanocolumns 312 are lower than the first nanocolumns 311. The second electrode is electrically insulated from the plurality of second nanocolumns 312 at the periphery of each of the nanocolumn groups 31A.

That is, in the light emitting apparatus 1B according to the present embodiment, the second nanocolumns 312 each having the shape of the first nanocolumns 311 except that part of the shape is missing are left at the periphery of each of the nanocolumn groups 31A, but the remaining second nanocolumns 312 are lower than the first nanocolumns 311, so that the second electrodes 60 are electrically insulated from the second nanocolumns 312. The second nanocolumns 312 thus do not form paths of the leakage current. The light emitting apparatus 1B according to the present embodiment therefore allows an increase in the light emission efficiency and can provide a desired amount of light emission at a desired wavelength in the proper light emitting area.

It is ideally desirable that no partially missing nanocolumn is left, but such a state is, however, difficult to achieve in practice. The reason for this is as follows: When the first etching leaves partially missing nanocolumns and the second etching is overdone in an attempt to completely remove the partially missing nanocolumns, the nanocolumns that are located in inner position and are therefore not damaged in the first etching will be damaged in the second etching. In view of the fact described above, even when the second nanocolumns 312 are left around the first nanocolumns 311 as a result of the second etching performed relatively lightly, the left second nanocolumns 312 do not form paths of the leakage current as long as the left second nanocolumns 312 are separate from the second electrodes 60 and electrically insulated therefrom, as in the present embodiment. Therefore, the state in which the second nanocolumn 312 are left, as in the present embodiment, allows more efficient suppression of the occurrence of the leakage current than an attempt to completely remove the second nanocolumns 312.

In the light emitting apparatus 1B according to the present embodiment, the height of the second nanocolumns 312 is smaller than or equal to ⅘ of the height of the first nanocolumns 311.

For example, when the height of the first nanocolumns 311 is 800 nm, which is the minimum value within the height range defined in the present embodiment, the height of the second nanocolumns 312 is 640 nm, which is 160 nm lower than the height of the first nanocolumns 311. In this case, the insulating layer 40 having the thickness of 160 nm is present between the second nanocolumns 312 and the second electrodes 60, as shown in FIG. 3. In consideration of the fact that a voltage of about 20 V is typically applied to the space between the first electrodes 50 and the second electrodes 60, the presence of the insulating layer 40 having the thickness of 160 nm is believed to be substantially sufficient to ensure the electrical insulation state. The inventor's knowledge has shown that when a gradually increasing voltage is applied to an insulating film deposited by using CVD and having a thickness of 100 nm, a minute leakage current starts to flow when the voltage reaches about 20 V. A film thickness at least 1.5 times greater than the film thickness where the minute leakage current starts to flow is believed to cause almost no problem.

In the light emitting apparatus 1B according to the present embodiment, the number of second nanocolumns 312 is smaller than the number of first nanocolumns 311.

According to the configuration described above, a large number of first nanocolumns 311 each having a normal planar shape and no missing portion are in the majority, thus ensuring light emitting sections 30 each having a desired area.

In the light emitting apparatus 1B according to the present embodiment, the second electrodes 60 overlap with the plurality of first nanocolumns 311 and the plurality of second nanocolumns 312 in the plan view.

According to the configuration described above, the occurrence of the leakage current can be suppressed even when the plurality of second nanocolumns 312 with missing portions overlap with the second electrodes 60 in the plan view.

The technical scope of the present disclosure is not limited to the embodiment described above, and a variety of changes can be made thereto to the extent that the changes do not depart from the substance of the present disclosure.

The aforementioned embodiment has been described with reference to the case where the light emitting layers are made of an InGaN-based material, and the light emitting layers can be made of any of a variety of other semiconductor materials in accordance with the wavelength of the light to be outputted from the light emitting layers. Examples of the semiconductor material may include an AlGaN-based, AlGaAs-based, InGaAs-based, InGaAsP-based, InP-based, GaP-based, and AlGaP-based semiconductor materials. The diameter of the columnar structural elements or the intervals at which the columnar structural elements are disposed may be changed as appropriate in accordance with the wavelength of the light to be outputted from the light emitting layers.

In addition to the above, the specific descriptions of the shape, the number, the arrangement, the material, and other factors of each component of the light emitting apparatus and the projector are not limited to those in the embodiment described above and can be changed as appropriate. The aforementioned embodiment has been described with reference to the case where the light emitting apparatus according to the present disclosure is used as a self-luminous imager. The light emitting apparatus according to the present disclosure may be used as an illuminator, and in addition to this, the present disclosure may be applied to a projector using, for example, transmissive liquid crystal display devices as the light modulators. Furthermore, the present disclosure may be applied to a projector using reflective liquid crystal display devices or digital micromirror devices as the light modulators.

The aforementioned embodiment has been described with reference to the case where the light emitting apparatus according to the present disclosure is incorporated in a projector, but not necessarily. The light emitting apparatus according to the present disclosure can also be used as minute light emitters of a μLED (micro-light emitting diode) display including the light emitters arranged in an array to display images. The light emitting apparatus according to the present disclosure can be used in a lighting apparatus, a headlight of an automobile, and other products.

A light emitting apparatus according to an aspect of the present disclosure may have the configuration below.

The light emitting apparatus according to the aspect of the present disclosure includes a substrate, a columnar section group provided on the substrate and formed from a plurality of columnar sections each having a laminated structure formed from a first semiconductor layer, a light emitting layer, and a second semiconductor layer, and electrodes which are provided on the plurality of columnar sections and via which electric current is injected into the plurality of columnar sections. The plurality of columnar sections include a plurality of first columnar sections and a plurality of second columnar sections disposed around the plurality of first columnar sections. The second columnar sections each have the shape of each of the first columnar sections except that part of the shape is missing. The second columnar sections are lower than the first columnar sections. The electrodes are electrically insulated from the plurality of second columnar sections.

In the light emitting apparatus according to the aspect of the present disclosure, the height of the second columnar sections may be smaller than or equal to ⅘ of the height of the first columnar sections.

In the light emitting apparatus according to the aspect of the present disclosure, the number of second columnar sections may be smaller than the number of first columnar sections.

In the light emitting apparatus according to the aspect of the present disclosure, the electrodes may overlap with the plurality of first columnar sections and the plurality of second columnar sections in the plan view viewed in the lamination direction of the laminated structure.

The light emitting apparatus according to the aspect of the present disclosure may further include an insulating layer that covers the columnar section group, and the electrodes may be electrically insulated from the second columnar sections via the insulating layer.

A projector according to another aspect of the present disclosure may have the configuration below.

The projector according to the other aspect of the present disclosure includes the light emitting apparatus according to the aspect of the present disclosure.

A method for manufacturing a light emitting apparatus according to another aspect of the present disclosure may have the configuration below.

The method for manufacturing a light emitting apparatus according to the other aspect of the present disclosure includes forming at a substrate a plurality of columnar sections each having a laminated structure formed from a first semiconductor layer, a light emitting layer, and a second semiconductor layer, forming a columnar section group by etching the plurality of columnar sections, etching the columnar section group, and forming electrodes electrically coupled to the columnar section group. In the forming of the plurality of columnar sections, the plurality of columnar sections include a plurality of first columnar sections and a plurality of second columnar sections disposed around the plurality of first columnar sections. The second columnar sections each have the shape of each of the first columnar sections except that part of the shape is missing. In the etching of the columnar section group, the second columnar sections are etched so as to be lower than the first columnar sections. In the forming of the electrodes, the electrodes are formed so as to be electrically insulated from the second columnar sections.

In the method for manufacturing a light emitting apparatus according to the other aspect of the present disclosure, in the forming of the electrodes, the electrodes may be formed so as to overlap with the plurality of first columnar sections and the plurality of second columnar sections in the plan view viewed in the lamination direction of the laminated structure.

The method for manufacturing a light emitting apparatus according to the other aspect of the present disclosure may further include forming an insulating layer that covers the columnar section group, and in the forming of the electrodes, the electrodes may be formed so as to be electrically insulated from the second columnar sections via the insulating layer.

What is claimed is:

1. A light emitting apparatus comprising:
a substrate;
a columnar section group including a plurality of columnar sections each having a laminated structure of a first semiconductor layer, a light emitting layer, and a second semiconductor layer; and
an electrode via which electric current is injected into the plurality of columnar sections, the plurality of columnar sections provided between the substrate and the electrode,
wherein the plurality of columnar sections include a plurality of first columnar sections and a plurality of second columnar sections disposed around the plurality of first columnar sections,
the second columnar sections each have a shape of each of the first columnar sections except that part of the shape is missing,
a height of each second columnar sections are lower than a height of each first columnar sections, and
the electrode is electrically insulated from the plurality of second columnar sections.

2. The light emitting apparatus according to claim 1, wherein a height of the second columnar sections is smaller than or equal to ⅘ of a height of the first columnar sections.

3. The light emitting apparatus according to claim 1, wherein the number of second columnar sections is smaller than the number of first columnar sections.

4. The light emitting apparatus according to claim 1, wherein the electrode overlaps with the plurality of first columnar sections and the plurality of second columnar sections in a plan view viewed in a lamination direction of the laminated structure.

5. The light emitting apparatus according to claim 4,
further comprising an insulating layer that covers the columnar section group, and
wherein the electrode is electrically insulated from the second columnar sections via the insulating layer.

6. A projector comprising the light emitting apparatus according to claim 1.

7. A method for manufacturing a light emitting apparatus, the method comprising:
forming at a substrate a plurality of columnar sections each having a laminated structure of a first semiconductor layer, a light emitting layer, and a second semiconductor layer;
forming a columnar section group by etching the plurality of columnar sections;
etching the columnar section group; and
forming an electrode electrically coupled to the columnar section group,
wherein in the forming of the plurality of columnar sections, the plurality of columnar sections include a plurality of first columnar sections and a plurality of second columnar sections disposed around the plurality of first columnar sections,
the second columnar sections each have a shape of each of the first columnar sections except that part of the shape is missing,
in the etching of the columnar section group, a height of each second columnar sections are etched so as to be lower than a height of each first columnar sections, and
in the forming of the electrode, the electrode is formed so as to be electrically insulated from the second columnar sections.

8. The method for manufacturing a light emitting apparatus according to claim 7, wherein in the forming of the electrode, the electrode is formed so as to overlap with the plurality of first columnar sections and the plurality of second columnar sections in a plan view viewed in a lamination direction of the laminated structure.

9. The method for manufacturing a light emitting apparatus according to claim 8,
the method further comprising forming an insulating layer that covers the columnar section group,
wherein in the forming of the electrode, the electrode is formed so as to be electrically insulated from the second columnar sections via the insulating layer.
